(19) United States
(12) Patent Application Publication
(10) Pub. No.: US 2023/0298982 A1
(43) Pub. Date: Sep. 21, 2023

(54) ELECTRONIC DEVICE WITH IMPROVED BOARD LEVEL RELIABILITY

(71) Applicant: Texas Instruments Incorporated, Dallas, TX (US)

(72) Inventor: Nazila Dadvand, Allen, TX (US)

(21) Appl. No.: 17/720,159

(22) Filed: Apr. 13, 2022

Related U.S. Application Data
(60) Provisional application No. 63/320,147, filed on Mar. 15, 2022.

(51) Int. Cl. H01L 23/495; H01L 21/48

(52) U.S. Cl. CPC H01L 23/49582; H01L 21/4821; H01L 23/49534; H01L 23/49548; H01L 24/48

(57) ABSTRACT

An electronic device includes a semiconductor die, a package structure enclosing the semiconductor die, and a conductive lead having first and second surfaces. The first surface has a bilayer exposed along a bottom side of the package structure, and the second surface is exposed along another side of the package structure. The bilayer includes first and second plated layers, the first plated layer on and contacting the first surface of the conductive lead and the second plated layer on and contacting the first plated layer and exposed along the bottom side of the package structure, where the first plated layer includes cobalt, and the second plated layer includes tin.

### CROSS-REFERENCE TO RELATED APPLICATION

This application claims priority to and benefit of U.S. Provisional Patent Application Ser. No. 63/320,147, filed on Mar. 15, 2022, and titled “Improvement of Board Reliability Performance in QFN Packages”, the contents of which are hereby fully incorporated by reference.

### BACKGROUND

Copper integrated circuit leads can be tin plated to mitigate deterioration of the material properties and enhance shelf life prior to soldering to a printed circuit board. However, tin plating of bare copper leads can impact board level reliability (BLR) of an electronic system by cracking and material defects at the solder joint of integrated circuit leads and solder pads of a printed circuit board. In addition, thermal dissipation through die attach structures is important for mitigating degradation and enhancing operation of electronic devices at high temperatures for compact and more highly integrated systems having smaller features and higher currents.

### SUMMARY

In one aspect, an electronic device includes a semiconductor die, a package structure enclosing the semiconductor die, and a conductive lead having first and second surfaces. The first surface has a bilayer exposed along a bottom side of the package structure, and the second surface is exposed along another side of the package structure. The bilayer includes first and second plated layers, the first plated layer on and contacting the first surface of the conductive lead and the second plated layer on and contacting the first plated layer and exposed along the bottom side of the package structure, where the first plated layer includes cobalt, and the second plated layer includes tin.

In another aspect, a method includes forming a first plated layer on a first surface of a conductive lead exposed along a bottom side of a molded structure in a panel array of prospective electronic devices, the first plated layer including cobalt, forming a second plated layer on the first plated layer, the second plated layer including tin, and separating an electronic device from the panel array with the conductive lead exposed along the bottom side of a respective package structure and a second surface of the conductive lead exposed along a first side of the package structure.

In a further aspect, an electronic device includes a semiconductor die, a die attach pad, a plated copper layer and a package structure. The semiconductor die has a side and a metal layer on the side of the semiconductor die, where the metal layer includes nickel. The die attach pad has an opening and the semiconductor die is attached to the die attach pad with the side of the semiconductor die facing the opening of the die attach pad. The plated copper layer extends on and contacts the metal layer, and the plated copper layer extends in the opening of the die attach pad from the metal layer in a direction away from the semiconductor die, and the package structure encloses a portion of the semiconductor die.

In another aspect, a method includes attaching a semiconductor die to a die attach pad with a metal layer along a side of the semiconductor die facing an opening of the die attach pad, the metal layer including nickel, as well as forming a package structure enclosing a portion of the semiconductor die and exposing the opening of the die attach pad. The method further includes performing an electroless plating process that forms a plated copper layer on and contacting the metal layer on the side of the semiconductor die, the plated copper layer extending in the opening of the die attach pad from the metal layer in a direction away from the semiconductor die and performing a package separation process that separates an electronic device from a panel array.

### BRIEF DESCRIPTION OF THE DRAWINGS

FIG. 1 is a perspective view of an electronic device.

FIG. 1A is a bottom view of the electronic device of FIG. 1.

FIG. 1B is a partial sectional side elevation view of the electronic device of FIGS. 1 and 1A.

FIG. 2 is a flow diagram of a method of fabricating an electronic device.

FIGS. 3-8 are partial sectional side elevation views of the electronic device of FIGS. 1-1B undergoing fabrication processing according to the method of FIG. 2.

FIG. 9 is a perspective view of an electronic device.

FIG. 9A is a bottom view of the electronic device of FIG. 9.

FIG. 9B is a sectional side elevation view of the electronic device of FIGS. 9 and 9A.

FIG. 10 is a flow diagram of a method of fabricating an electronic device.

FIGS. 11-18 are partial sectional side elevation views of the electronic device of FIGS. 9-9B undergoing fabrication processing according to the method of FIG. 10.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections.

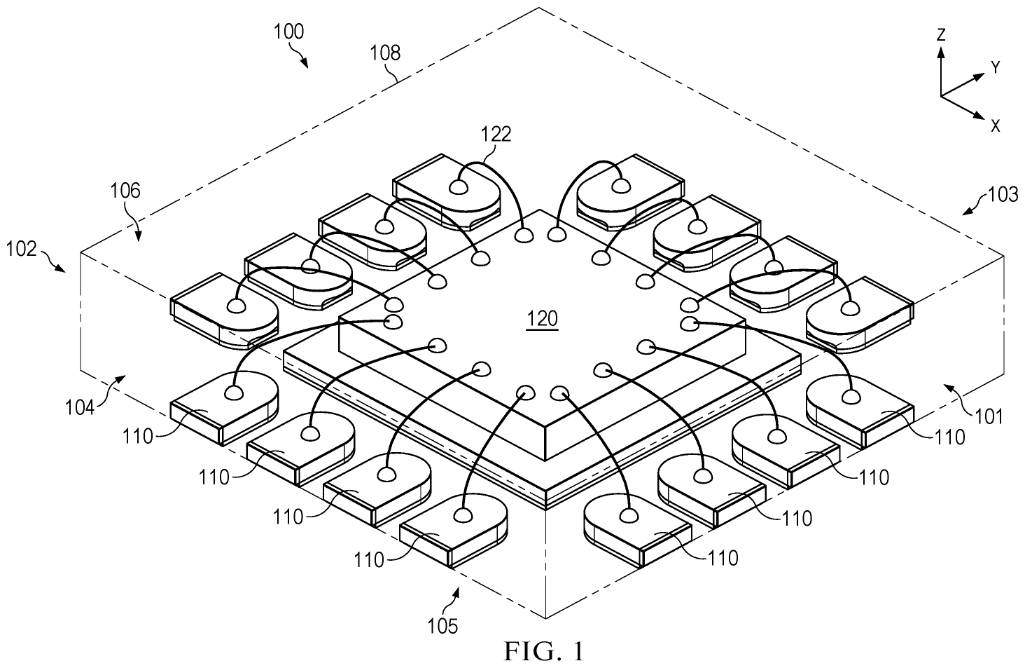

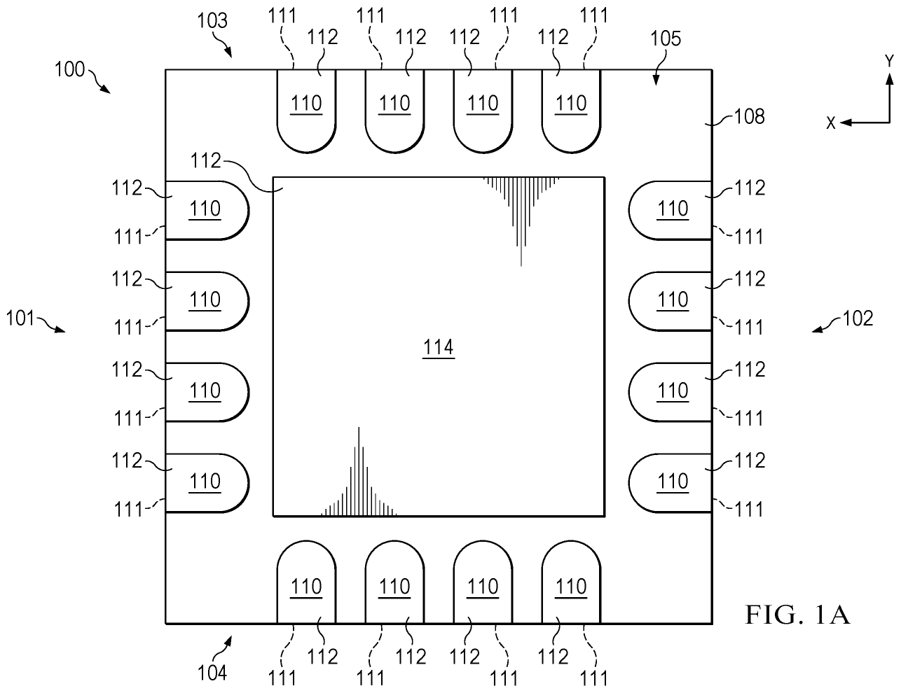

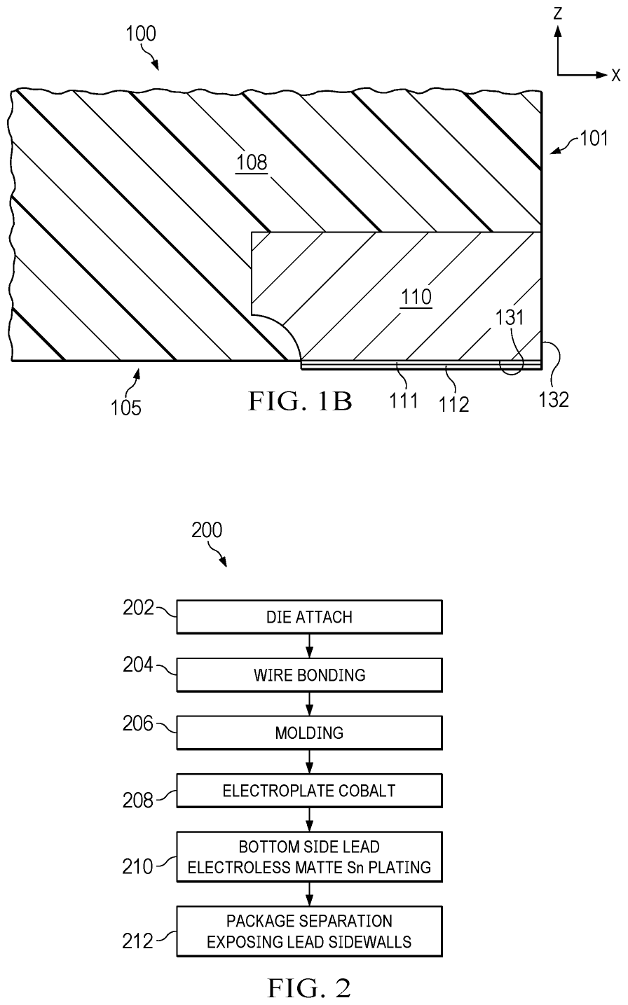

FIGS. 1-1B show an electronic device 100 with copper leads electroplated after molding with cobalt and tin to improve BLR performance by electroplated cobalt with minimized defect and larger grain sizes that provides a diffusion barrier layer against interdiffusion of copper and tin. The formation of inter-metallic compounds (IMCs) such as Cu₃Sn and Cu₆Sn₅ is decelerated resulting in higher BLR performance since cobalt and copper have very low solubility in each other. Moreover, the cobalt-tin intermetallic has high fracture toughness and high ductility resulting in solder voiding at the interface and reduced chance of cracking at the interface of cobalt-copper IMC to the matte plated tin. Described examples enable copper integrated circuit leads to be tin plated to mitigate deterioration of the material properties and enhance shelf life prior to soldering to a printed circuit board while improving BLR of an electronic system once the electronic device is soldered to a host printed circuit board.

The electronic device 100 of FIGS. 1-1B is shown in an example position in a three-dimensional space with respective first, second, and third mutually orthogonal directions X, Y, and Z. The electronic device 100 has opposite first and second sides 101 and 102 that are spaced apart from one another along the first direction X and extend along the second direction Y. The electronic device 100 also includes third and fourth sides 103 and 104 spaced apart from one another along the second direction Y, as well as a bottom side 105, and a top side 106 that is spaced apart from the bottom side 105 along the third direction Z. The electronic device 100 includes a molded package structure 108 that includes the sides 101-106. In the illustrated example, the bottom and top sides 105 and 106 are generally planar and extend in respective X-Y planes of the first and second directions X and Y.

The electronic device 100 includes conductive leads 110 (e.g., copper) along the lateral sides 101-104 to form a quad flat no-lead (QFN) package structure. In another implementation the device has conductive leads on two opposite sides to provide a dual flat no-lead (DFN) package structure (not shown). As best shown in FIG. 1B, the individual conductive leads 110 have a first surface 131 and a second surface 132. The first surface 131 has a bilayer exposed outside the package structure 108 along the bottom side 105 of the package structure 108, and the second surface 132 is exposed outside the package structure 108 along the first side 101 of the package structure 108. The bilayer includes a first plated layer 111 and a second plated layer 112. The first plated layer 111 is on and contacting the first surface 131 of the conductive lead 110. The first plated layer 111 includes cobalt. In one example, the first layer 111 has a thickness along the third direction Z of approximately 0.5 μm or more and approximately 2.0 μm or less. The second plated layer 112 is on and contacting the first plated layer 111 and the second plated layer 112 is exposed outside the package structure 108 along the bottom side 105 of the package structure 108. The second plated layer 112 includes tin, for example, matte tin with a dull finish. FIG. 1B shows a partial sectional view of an example conductive lead 110 along the first side 101 of the electronic device 100. The conductive leads on the other lateral sides 102-104 of the electronic device 100 are similarly constructed. As shown in FIG. 1, the electronic device 100 also includes a semiconductor die 120 enclosed by the package structure 108. The semiconductor die 120 has conductive bond pads electrically connected to respective leads 110 by bond wires 122.

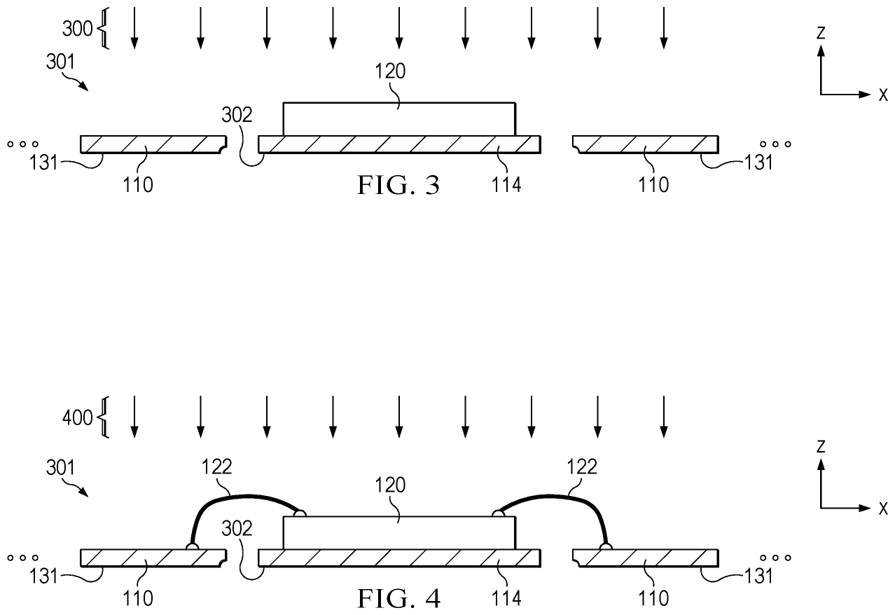

FIG. 2 shows a method 200 of fabricating an electronic device and FIGS. 3-8 show the electronic device 100 undergoing fabrication processing according to the method 200. The method 200 includes die attach processing at 202. FIG. 3 shows one example, in which a die attach process 300 is performed that attaches the semiconductor die 120 to a die attach pad 114 of a starting lead frame strip (e.g., copper) that also includes the prospective leads 110. The die attach pad 114 has a lower surface 302 and the leads 110 have lower first surfaces 131 as shown in FIG. 3. In one example, the starting lead frame has multiple prospective device sections arranged in a panel array 301 of rows and columns (not shown) of prospective electronic devices 100. The die attach process 300 includes concurrent or sequential placement of multiple semiconductor dies 120 to respective die attach pads 114 of the panel array 301.

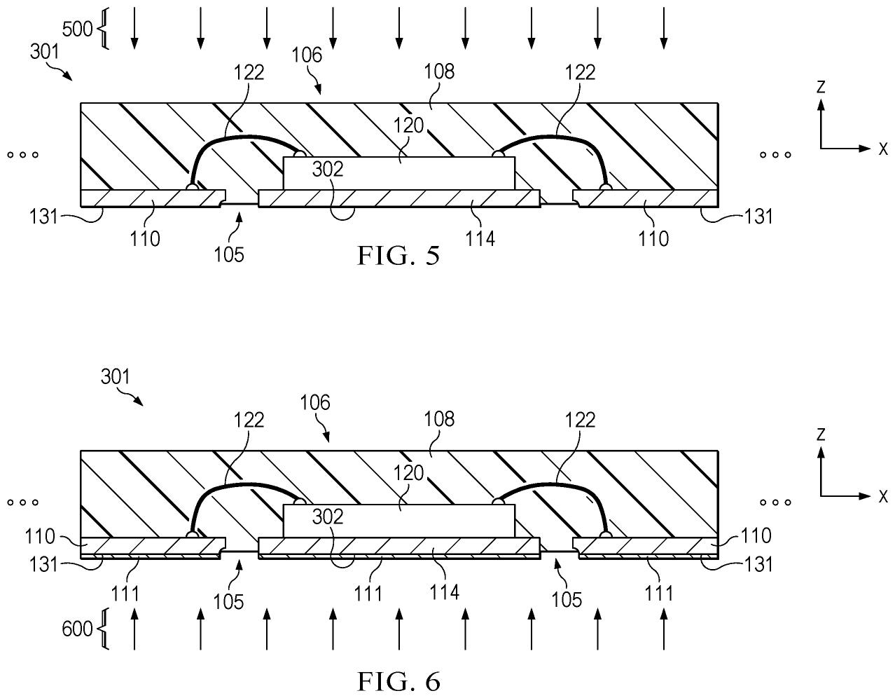

The method 200 continues at 204 with formation of electrical connections including electrically coupling one or more conductive terminals (e.g., bond pads) of the die 120 to respective conductive leads 110, as well as any die-to-die connections required for a given electronic device design (e.g., die-to-die connections for a multiple chip module or MCM device, not shown). FIG. 4 shows one example, in which a wire bonding process 400 is performed that forms bond wires 122 between respective conductive bond pads of the semiconductor die 120 and associated ones of the conductive leads 110 of the starting lead frame in the panel array 301. The method 200 also includes performing a molding process at 206 that forms a molded package structure 108 that encloses the semiconductor die 120 and the bond wires 122. FIG. 5 shows one example, in which a molding process 500 is performed that forms the molded package structure 108 that encloses the semiconductor die 120 and the bond wires 122.

At 208, the method 200 includes performing a first plating process to plate the first surface 131 of the conductive leads 110 with a first plated layer 111 that includes cobalt. FIG. 6 shows one example, in which a first plating process 600 is performed that forms the first plated layer 111 on the first surfaces 131 of a conductive leads 110 exposed along the bottom side 105 of the molded structure 108 in the panel array 301 of prospective electronic devices 100. The first plating process 600 in one example is an electroplating process that forms the first plated layer 111 to a thickness of approximately 0.5 μm or more and approximately 2.0 μm or less on the exposed first surfaces 131 of the conductive leads 110, where the first plated layer 111 includes cobalt. As discussed above, post molding plating of the exposed first surfaces 131 of the conductive leads 110 an underlayer that includes cobalt prior to plating of matte tin improves the BLR performance by reducing defects and including larger grain sizes that provide a diffusion barrier layer against interdiffusion of copper and tin in the subsequent tin plating.

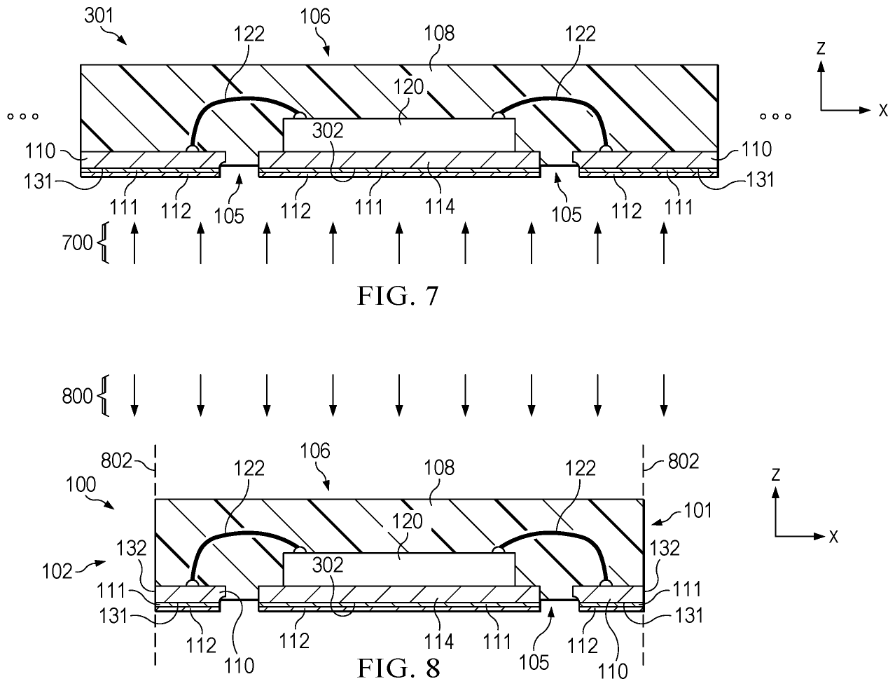

The method 200 continues with matte tin plating at 210. FIG. 7 shows one example, in which a second plating process 700 is performed that forms the second plated layer 112 on the first plated layer 111, where the second plated layer 112 includes tin. In one example, the second plating process 700 is an electroless plating process that forms the second plated layer 112 on the first plated layer 111. The presence of the cobalt in the first plated layer 111 decelerates the formation of crack susceptible inter-metallic compounds (IMCs) such as Cu₃Sn and Cu₆Sn₅ in the bilayer resulting in higher BLR performance since cobalt and copper have very low solubility in each other. Moreover, the cobalt-tin intermetallic has high fracture toughness and high ductility resulting in solder voiding at the interface and reduced chance of cracking at the interface of cobalt-copper IMC to the matte plated tin. Described examples enable copper integrated circuit leads to be tin plated to mitigate deterioration of the material properties and enhance shelf life prior to soldering to a printed circuit board while improving BLR of an electronic system once the electronic device is soldered to a host printed circuit board.

The method 200 continues with package separation at 212 in FIG. 2. FIG. 8 shows one example, in which a package separation process 800 is performed that separates an electronic device 100 from the panel array 301, for example, by saw cutting, laser cutting, or other suitable processing along lines 802. The separation process 800 separates the individual semiconductor device 100 with the cobalt and tin-plated surface 131 of the conductive lead 110 exposed along the bottom side 105 of a respective package structure 108. The package separation process 800 exposes the second surfaces 132 of the conductive leads 110 along the sides 101-104 of the package structure 108.

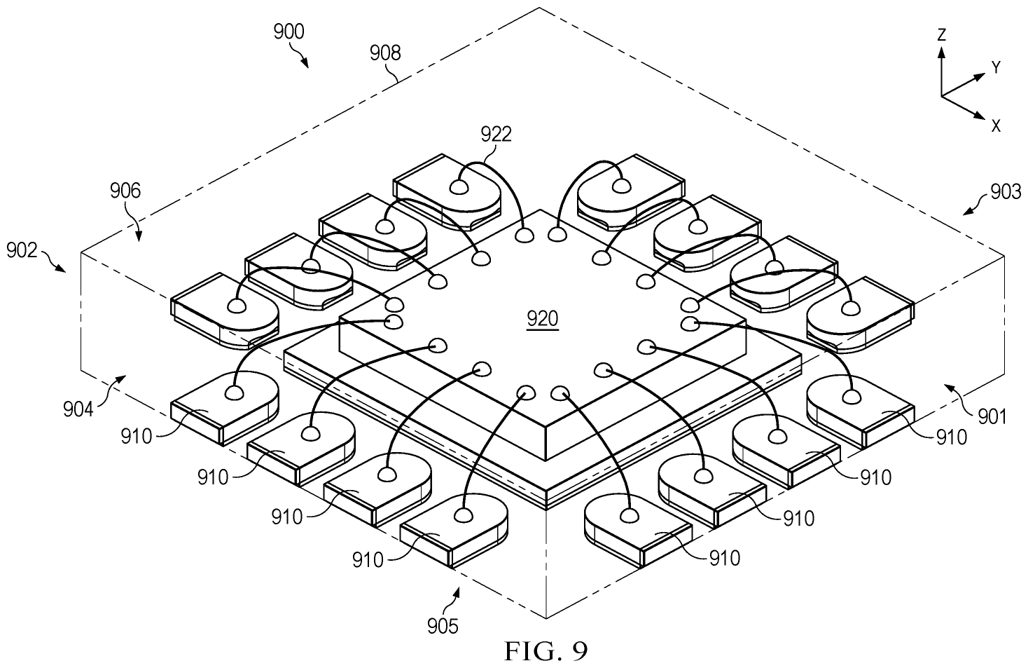

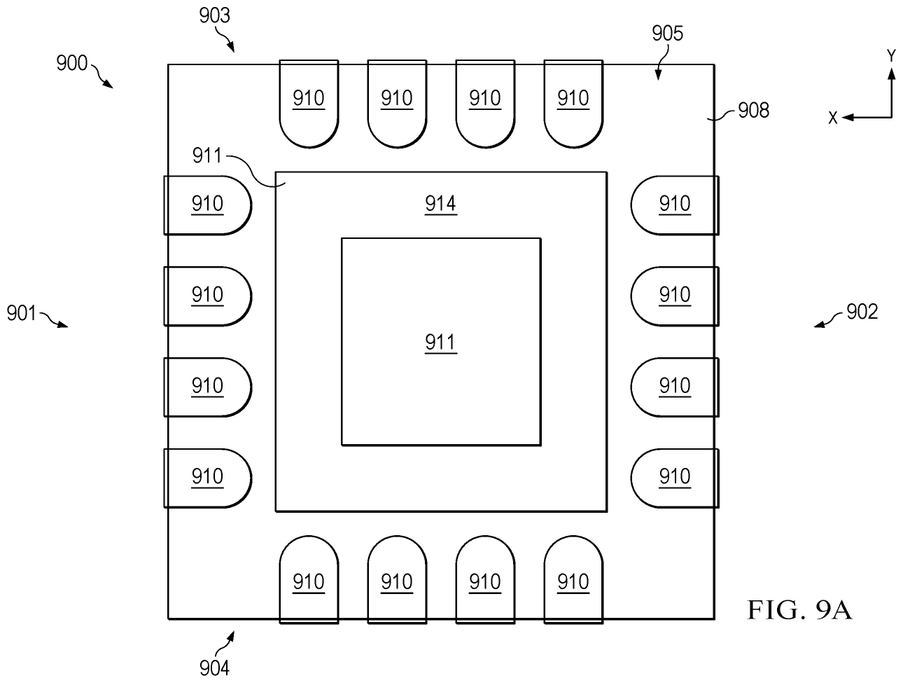

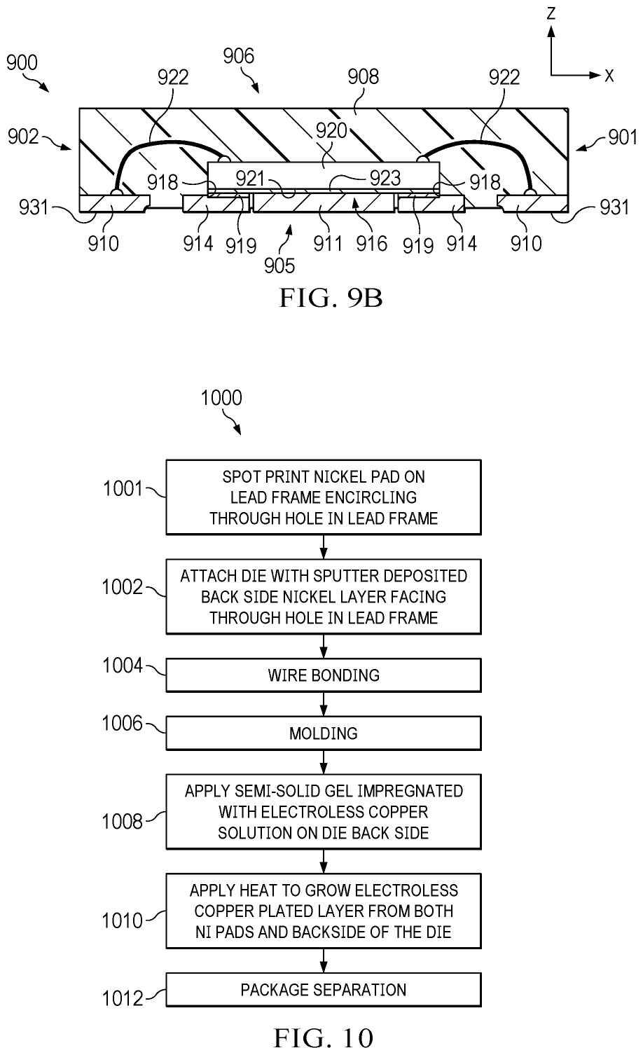

FIGS. 9-9B show an electronic device 900 with enhanced bottom side thermal dissipation through a plated copper structure in an opening of a die attach pad. Good thermal dissipation through the die attachment structure helps mitigate device degradation and enhance device operation at high temperatures. The electronic device 900 is shown in an example position in a three-dimensional space with respective first, second, and third mutually orthogonal directions X, Y, and Z. The electronic device 900 has opposite first and second sides 901 and 902 that are spaced apart from one another along the first direction X and extend along the second direction Y. The electronic device 900 also includes third and fourth sides 903 and 904 spaced apart from one another along the second direction Y, as well as a bottom side 905, and a top side 906 that is spaced apart from the bottom side 905 along the third direction Z. The electronic device 900 includes a molded package structure 908 that includes the sides 901-906. In the illustrated example, the bottom and top sides 905 and 906 are generally planar and extend in respective X-Y planes of the first and second directions X and Y.

The electronic device 900 includes conductive leads 910 (e.g., copper) along the lateral sides 901-904 to form a quad flat no-lead (QFN) package structure. In another implementation the device has conductive leads on two opposite sides to provide a dual flat no-lead (DFN) package structure (not shown). As best shown in FIG. 9B, the individual conductive leads 910 have a bottom surface 931 exposed along the bottom side 905 of the package structure 908, and the conductive leads 910 on the other lateral sides 902-904 of the electronic device 900 are similarly constructed.

As shown in FIGS. 9 and 9B, the electronic device 900 also includes a plated copper layer 911 to facilitate thermal transfer downward from a semiconductor die 920 enclosed by the package structure 908 and attached to a die attach pad 914. The die attach pad 914 has an opening 916 under a portion of the semiconductor die 920. In the example of FIG. 9B, the die attach pad 914 has a recessed ledge 918 that surrounds the opening 916 and the semiconductor die 920 is attached to the ledge 918 of the die attach pad 914. The semiconductor die 920 has conductive bond pads electrically connected to respective leads 910 by bond wires 922. The package structure 908 encloses at least a portion of the semiconductor die 920.

As shown in FIG. 9B, the semiconductor die 920 has a bottom side 921 and a metal layer 923 that includes nickel extends on the bottom side 921 of the semiconductor die 120. In one example, the metal layer 923 has a thickness along the third direction Z of approximately 50 nm. The semiconductor die 920 is attached to the die attach pad 914 with the side 921 of the semiconductor die 920 facing the opening 916 of the die attach pad 914. In this example, a second metal layer 919 (e.g., a pad) that includes nickel extends on and contacts the ledge 918 of the die attach pad 914. The second metal layer 919 also contacts the metal layer 923 and the plated copper layer 911. In another implementation, the ledge 918 and the second metal layer 919 are omitted, and the semiconductor die 120 is attached to the top side of the die attach pad 914. The metal layer 923 facilitates electroless plating to form the plated copper layer 911 during fabrication following molding operations. The plated copper layer 911 extends in the opening 916 of the die attach pad 914 from the metal layer 923 downward along the third direction Z away from the semiconductor die 920. In one example, the plated copper layer 911 extends to the bottom side 905 of the electronic device 900 to allow soldering to a host printed circuit board (not shown). The second metal layer 923, when included, also facilitates electroless plating to form the plated copper layer 911. In the illustrated example, the plated copper layer 911 extends on and contacts the metal layer 923. The second metal layer 919 is thicker than the metal layer 923 along the third direction Z.

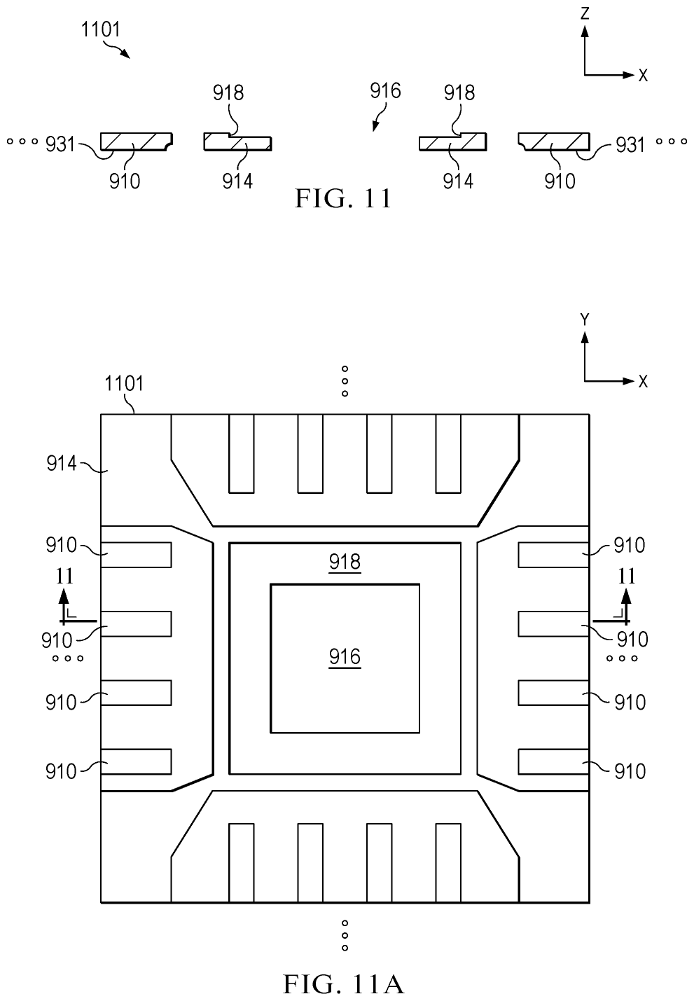

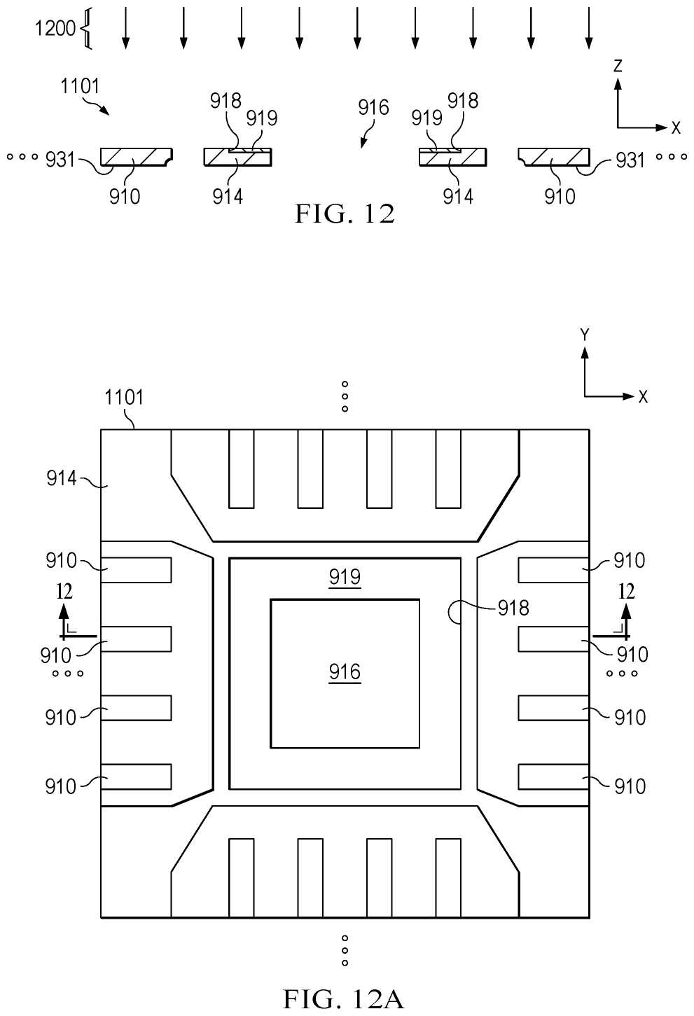

Referring also to FIGS. 10-18, FIG. 10 shows a method 1000 of fabricating an electronic device and FIGS. 11-18 show the electronic device 900 undergoing fabrication processing according to the method 1000. The method 1000 includes spot printing the second metal layer 919 on the ledge 918 of the die attach pad 914 of a starting lead frame panel or strip. FIGS. 11 and 11A show one example of a starting lead frame panel array 1101 which includes multiple prospective device areas arranged in an array of rows and columns (not shown). Each prospective device area of the lead frame panel array 1101 includes a die attach pad structure 914 with an opening 916 and a recessed ledge feature 918 that laterally surrounds the opening 916. In FIGS. 12 and 12A a printing or other deposition process 1200 is performed that deposits nickel in select portions on the ledge 918 to form the second metal layer 919 thereon.

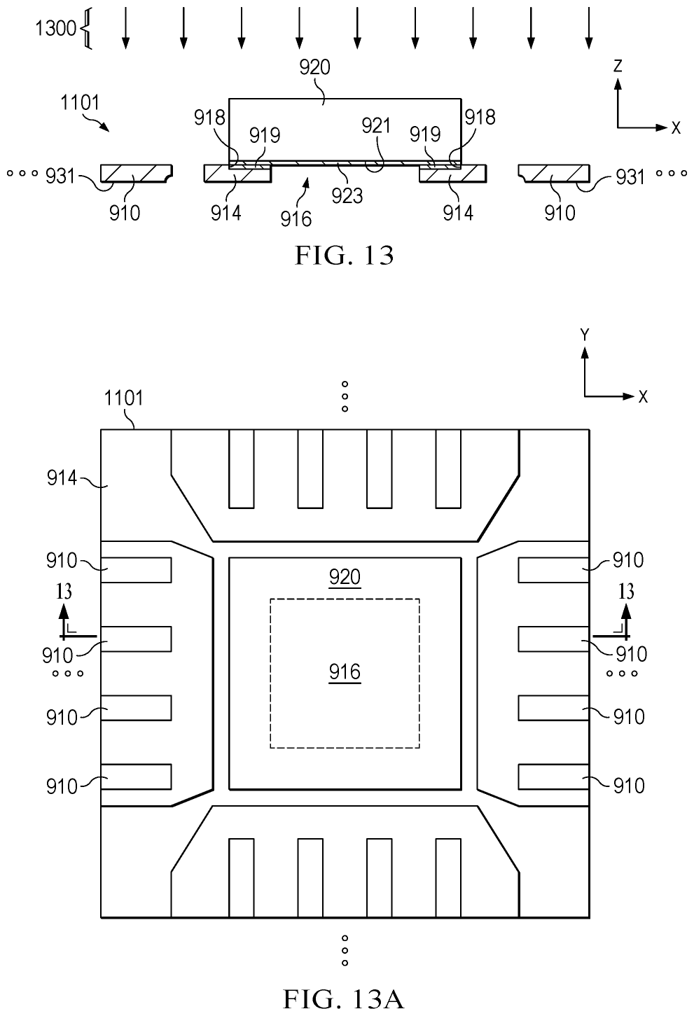

At 1002 in FIG. 10, the method 1000 continues with die attach processing. In the illustrated implementation, the bottom side 921 of the semiconductor die 920 includes the nickel metal layer 923. In one example, the metal layer 923 has a thickness along the third direction Z of approximately 50 nm, and the second metal layer 919 is thicker than the metal layer 923. FIGS. 13 and 13A show an example of the processing at 1002, in which an automated pick and place die attach process 1300 is performed that attaches the bottom side 921 of the semiconductor die 920 to the die attach pad 914 with the nickel metal layer 923 along the bottom side 921 of the semiconductor die 920 facing the opening 916 of the die attach pad 914. In the illustrated example with the die attach pad ledge 918 and the second metal layer 919 thereon, the semiconductor die 920 is attached to the die attach pad 914 with a peripheral portion of the metal layer 923 along the side 921 of the semiconductor die 920 on and contacting a second metal layer 919 on the ledge 918 of the die attach pad 914.

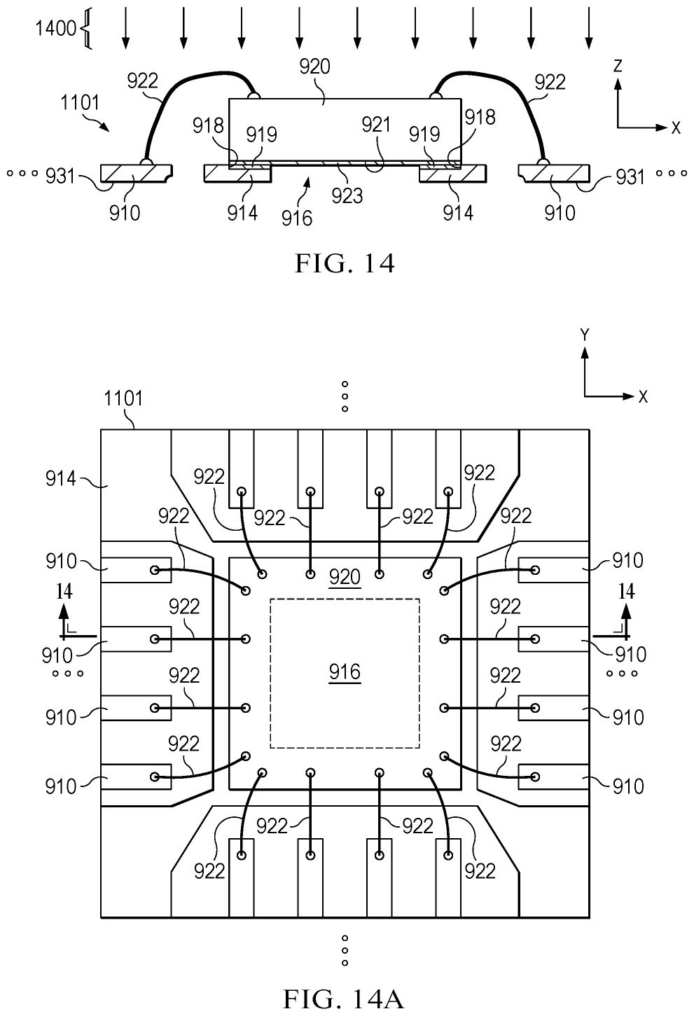

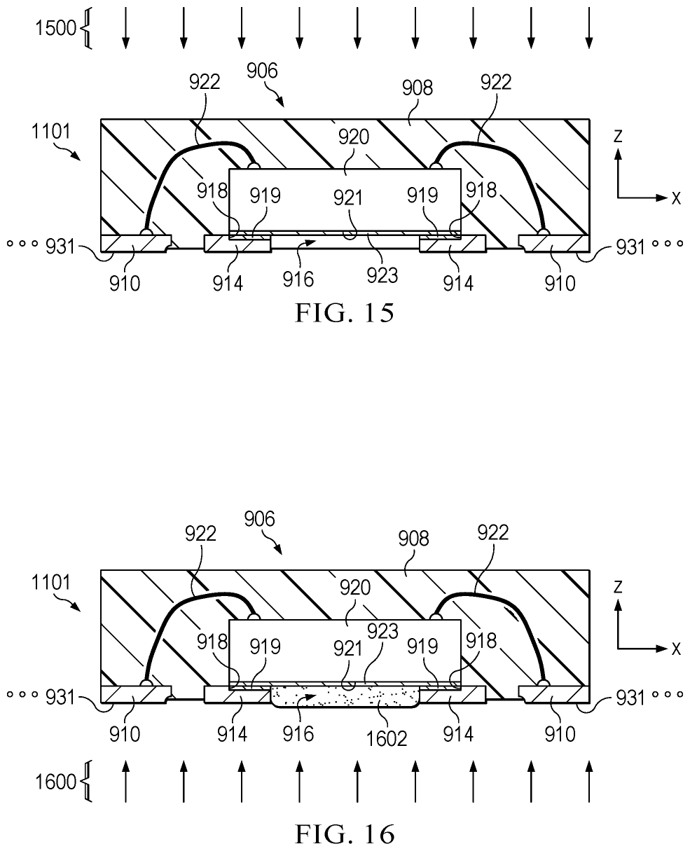

The method 1000 continues at 1004 with formation of electrical connections including electrically coupling one or more conductive terminals (e.g., bond pads) of the die 920 to respective conductive leads 910, as well as any die-to-die connections required for a given electronic device design. FIGS. 14 and 14A show one example, in which a wire bonding process 1400 is performed that forms the bond wires 922 between respective conductive bond pads of the semiconductor die 920 and associated ones of the conductive leads 910 of the starting lead frame in the panel array 1101. The method 1000 also includes performing a molding process at 1006 that forms a molded package structure 908 that encloses at least a portion of the semiconductor die 920 and the bond wires 922. FIG. 15 shows one example, in which a molding process 1500 is performed that forms the molded package structure 908 that encloses the semiconductor die 920 and the bond wires 922 and exposes the opening 916 of the die attach pad 914.

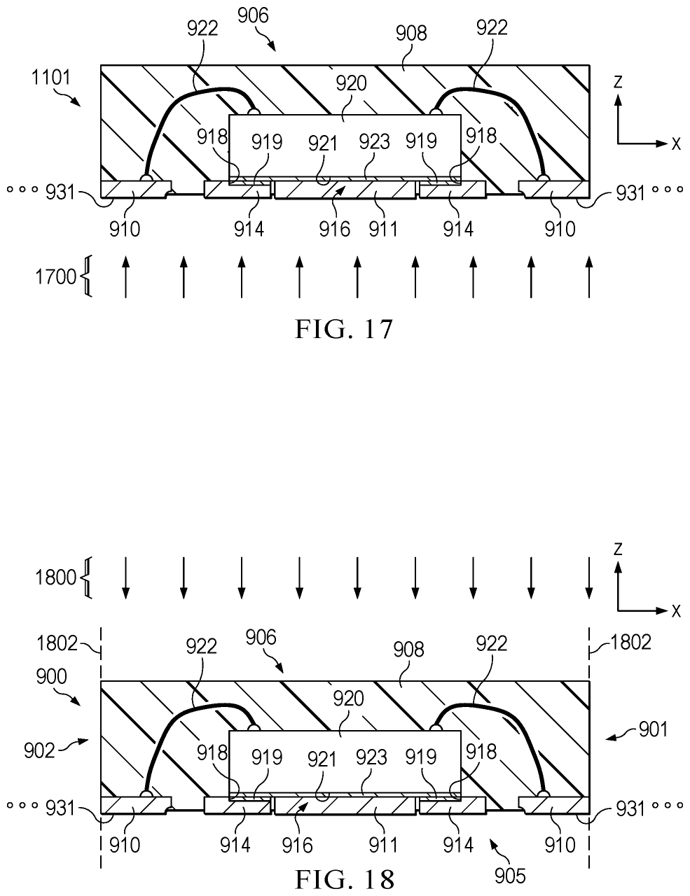

The method 100 further includes electroless plating at 1008 and 1010 to form the plated copper layer 911 on and contacting the metal layer 923 on the side 921 of the semiconductor die 920, such that the plated copper layer 911 extends in the opening 916 of the die attach pad 914 from the metal layer 923 in the third direction Z away from the semiconductor die 920. FIGS. 16 and 17 show one example, in which a deposition process 1600 is performed in FIG. 16 that applies a semi-solid gel 1602 on the backside of the semiconductor die 920 in the opening 916. The gel 1602 in this example is impregnated with electroless copper solution. In FIG. 17, a thermal process 1700 is performed that applies heat to grow electroless copper from the nickel metal layers 919 and 923 to form the plated copper layer 911 on and contacting the metal layer 923 on the side 921 of the semiconductor die 920.

The method 1000 also includes performing a package separation process at 1012 to separate the fabricated electronic devices 900 from the starting panel array 1101. FIG. 18 shows one example, in which a package separation process 1800 is performed that separates an electronic device 900 from the panel array 1101, for example, by saw cutting, laser cutting, or other suitable processing along lines 1802. The separation process 1800 separates the individual semiconductor device 900 with the bottom surfaces 931 of the conductive leads 910 exposed along the bottom side 905 of a respective package structure 908, and the package separation process 1800 exposes the side surfaces of the conductive leads 910 along the sides 901-904 of the package structure 908 as shown in FIGS. 9-9B above.

The above examples are merely illustrative of several possible implementations of various aspects of the present disclosure, wherein equivalent alterations and/or modifications will occur to others skilled in the art upon reading and understanding this specification and the annexed drawings. Unless otherwise stated, “about,” “approximately,” or “substantially” preceding a value means+/−10 percent of the stated value. Modifications are possible in the described examples, and other implementations are possible, within the scope of the claims.

What is claimed is:

1. An electronic device, comprising:
a semiconductor die;
a package structure enclosing the semiconductor die; and
a conductive lead having a first surface and a second surface, the first surface having a bilayer exposed outside the package structure along a bottom side of the package structure, and the second surface exposed outside the package structure along another side of the package structure, the bilayer including a first plated layer and a second plated layer, the first plated layer on and contacting the first surface of the conductive lead, the second plated layer on and contacting the first plated layer and exposed outside the package structure along the bottom side of the package structure, the first plated layer including cobalt, and the second plated layer including tin.

2. The electronic device of claim 1, wherein the first plated layer has a thickness of approximately 0.5 μm or more and approximately 2.0 μm or less.

3. The electronic device of claim 1, comprising a second conductive lead having a first surface and a second surface, the first surface of the second conductive lead having a second bilayer exposed outside the package structure along the bottom side of the package structure, and the second surface of the second conductive lead exposed outside the package structure along a further side of the package structure, the second bilayer including a first layer and a second layer, the first layer of the second bilayer on and contacting the first surface of the second conductive lead, the second layer of the second bilayer on and contacting the first layer of the second bilayer and exposed outside the package structure along the bottom side of the package structure, the first layer of the second bilayer including cobalt, and the second layer of the second bilayer including tin.

4. A method of fabricating an electronic device, the method comprising:
performing a first plating process that forms a first plated layer on a first surface of a conductive lead exposed along a bottom side of a molded structure in a panel array of prospective electronic devices, the first plated layer including cobalt;
performing a second plating process that forms a second plated layer on the first plated layer, the second plated layer including tin; and
performing a package separation process that separates an electronic device from the panel array, with the conductive lead exposed along the bottom side of a respective package structure, the package separation process exposing a second surface of the conductive lead along a first side of the package structure.

5. The method of claim 4, wherein the first plating process is an electroplating process that forms the first plated layer to a thickness of approximately 0.5 μm or more and approximately 2.0 μm or less on the first surface of the conductive lead.

6. The method of claim 5, wherein the second plating process is an electroless plating process that forms the second plated layer on the first plated layer.

7. The method of claim 4, wherein the second plating process is an electroless plating process that forms the second plated layer on the first plated layer.

8. An electronic device, comprising:
a semiconductor die having a side and a metal layer, the metal layer on the side of the semiconductor die, and the metal layer including nickel;
a die attach pad having an opening, the semiconductor die attached to the die attach pad with the side of the semiconductor die facing the opening of the die attach pad;
a plated copper layer on and contacting the metal layer, the plated copper layer extending in the opening of the die attach pad from the metal layer in a direction away from the semiconductor die; and
a package structure enclosing a portion of the semiconductor die.

9. The electronic device of claim 8, wherein:
the die attach pad has a ledge and that surrounds the opening; and
the semiconductor die is attached to the ledge of the die attach pad.

10. The electronic device of claim 9, further comprising a second metal layer on and contacting the ledge of the die attach pad, the second metal layer contacting the metal layer and the plated copper layer, and the second metal layer including nickel.

11. The electronic device of claim 10, wherein the metal layer has a thickness along the direction of approximately 50 nm.

12. The electronic device of claim 10, wherein the second metal layer is thicker than the metal layer along the direction.

13. The electronic device of claim 8, wherein the metal layer has a thickness along the direction of approximately 50 nm.

14. A method of fabricating an electronic device, the method comprising:
attaching a semiconductor die to a die attach pad with a metal layer along a side of the semiconductor die facing an opening of the die attach pad, the metal layer including nickel;
performing a molding process that forms a package structure enclosing a portion of the semiconductor die and exposing the opening of the die attach pad;
performing an electroless plating process that forms a plated copper layer on and contacting the metal layer on the side of the semiconductor die, the plated copper layer extending in the opening of the die attach pad from the metal layer in a direction away from the semiconductor die; and
performing a package separation process that separates an electronic device from a panel array.

15. The method of claim 15, wherein attaching the semiconductor die to the die attach pad includes attaching the semiconductor die to a ledge of the die attach pad that surrounds the opening.

16. The method of claim 15, wherein attaching the semiconductor die to the die attach pad includes attaching the semiconductor die with a peripheral portion of the metal layer along the side of the semiconductor die on and contacting a second metal layer on the ledge of the die attach pad, the second metal layer including nickel.

17. The method of claim 16, wherein the metal layer has a thickness of approximately 50 nm.

18. The method of claim 16, wherein the second metal layer is thicker than the metal layer.

19. The method of claim 15, wherein the metal layer has a thickness of approximately 50 nm.

20. The method of claim 14, wherein the metal layer has a thickness of approximately 50 nm.
